(19) United States
(12) Patent Application Publication
(10) Pub. No.: US 2024/0379512 A1
(43) Pub. Date: Nov. 14, 2024

(54) SEMICONDUCTOR DEVICE

(71) Applicant: Mitsubishi Electric Corporation, Tokyo (JP)

(72) Inventors: Tomokazu KANNA, Tokyo (JP); Akiyoshi MASUDA, Tokyo (JP)

(73) Assignee: Mitsubishi Electric Corporation, Tokyo (JP)

(21) Appl. No.: 18/625,136

(22) Filed: Apr. 2, 2024

(30) Foreign Application Priority Data
May 10, 2023 (JP) 2023-077698

(51) Int. Cl. H01L 23/498; H01L 23/00

(52) U.S. Cl. CPC H01L 23/49811; H01L 23/49838; H01L 24/49; H01L 2224/49171; H01L 2924/30107

(57) ABSTRACT

A semiconductor device includes: a first circuit pattern, a second circuit pattern, a third circuit pattern, and a fourth circuit pattern; a semiconductor chip and a first electrode arranged on the first circuit pattern; a second electrode disposed on the second circuit pattern; a third electrode disposed on the third circuit pattern; and a fourth electrode disposed on the fourth circuit pattern, a pad disposed on the semiconductor chip and the second circuit pattern are connected via first wiring, a surface of the semiconductor chip and the third circuit pattern are connected via second wiring, the surface of the semiconductor chip and the fourth circuit pattern are connected via third wiring, the second wiring and the third wiring are arranged on the same side of the surface of the semiconductor chip and in parallel with each other, and the first wiring is disposed on an opposite side from the third wiring.

### BACKGROUND OF THE INVENTION

### Field of the Invention

The present disclosure relates to semiconductor devices.

### Description of the Background Art

Technology of generating, due to mutual induction from first emitter wiring, an induced electromotive force in second emitter wiring during switching operation of a semiconductor device has been disclosed (see WO 2017/209191, for example).

In technology disclosed in WO 2017/209191, the induced electromotive force is generated not only in the second emitter wiring but also in gate wiring due to mutual induction from the first emitter wiring. The induced electromotive force generated in the gate wiring is exerted to counteract the induced electromotive force generated in the second emitter wiring. This results in a problem in that an effect of suppressing an increase in gate voltage is reduced to reduce short circuit capability of the semiconductor device.

### SUMMARY

The present disclosure has been conceived to solve such a problem, and it is an object of the present disclosure to provide a semiconductor device having improved short circuit capability.

A semiconductor device according to the present disclosure includes: an insulating substrate; a first circuit pattern, a second circuit pattern, a third circuit pattern, and a fourth circuit pattern arranged on the insulating substrate; a semiconductor chip and a first electrode arranged on the first circuit pattern; a second electrode disposed on the second circuit pattern; a third electrode disposed on the third circuit pattern; and a fourth electrode disposed on the fourth circuit pattern, wherein a pad disposed on the semiconductor chip and the second circuit pattern are connected via first wiring, a surface of the semiconductor chip and the third circuit pattern are connected via second wiring, the surface of the semiconductor chip and the fourth circuit pattern are connected via third wiring, the second wiring and the third wiring are arranged on the same side of the surface of the semiconductor chip and in parallel with each other, and the first wiring is disposed on an opposite side from the third wiring.

According to the present disclosure, short circuit capability can be improved.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a top view illustrating one example of a configuration of a semiconductor device according to Embodiment 1;

FIG. 2 is a circuit diagram of the semiconductor device illustrated in FIG. 1;

FIG. 3 is a diagram for describing a direction of an induced electromotive force generated due to mutual induction;

FIG. 4 is a top view illustrating one example of a configuration of a semiconductor device according to Embodiment 3;

FIG. 5 is a circuit diagram of the semiconductor device illustrated in FIG. 4; FIG. 6 is a side view illustrating one example of a configuration of a semiconductor device according to Embodiment 4; and

FIG. 7 is a top view of the semiconductor device illustrated in FIG. 6.

### DESCRIPTION OF THE PREFERRED EMBODIMENTS

### Embodiment 1

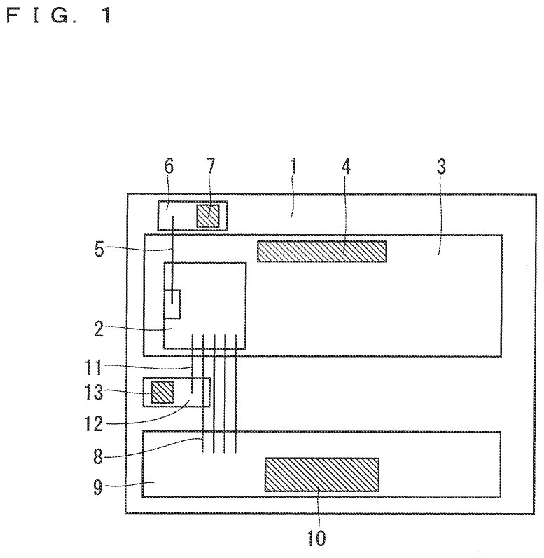

FIG. 1 is a top view illustrating one example of a configuration of a semiconductor device according to Embodiment 1.

A collector pattern 3 (first circuit pattern), a gate pattern 6 (second circuit pattern), a first emitter pattern 9 (third circuit pattern), and a second emitter pattern 12 (fourth circuit pattern) are arranged on a front surface of an insulating substrate 1. The first emitter pattern 9 and the second emitter pattern 12 are arranged on the same side of the collector pattern 3. The gate pattern 6 is disposed on an opposite side of the collector pattern 3 from the second emitter pattern 12.

A semiconductor chip 2 and a collector electrode 4 (first electrode) are arranged on the collector pattern 3. The collector pattern 3, the semiconductor chip 2, and the collector electrode 4 are electrically connected. The collector electrode 4 is connected to unillustrated external wiring.

A first emitter electrode 10 (third electrode) is disposed on the first emitter pattern 9. The first emitter pattern 9 and the first emitter electrode 10 are electrically connected. The first emitter pattern 9 and a surface of the semiconductor chip 2 are electrically connected via first emitter wiring 8 (second wiring). The first emitter electrode 10 is connected to unillustrated external wiring.

A second emitter electrode 13 (fourth electrode) is disposed on the second emitter pattern 12. The second emitter pattern 12 and the second emitter electrode 13 are electrically connected. The second emitter pattern 12 and the surface of the semiconductor chip 2 are electrically connected via second emitter wiring 11 (third wiring). The first emitter wiring 8 and the second emitter wiring 11 are arranged on the same side of the surface of the semiconductor chip 2 and in parallel with each other.

A gate electrode 7 (second electrode) is disposed on the gate pattern 6. The gate pattern 6 and the gate electrode 7 are electrically connected. The gate pattern 6 and a gate pad disposed on the surface of the semiconductor chip 2 are electrically connected via gate wiring 5 (first wiring). The gate wiring 5 is disposed on an opposite side from the second emitter wiring 11.

In the semiconductor device illustrated in FIG. 1, a gate signal is input into each of the gate electrode 7 and the second emitter electrode 13, and a voltage across and a current between the collector electrode 4 and the first emitter electrode 10 can be controlled in response to a voltage value indicated by the gate signal.

The insulating substrate 1 is formed of ceramics, such as aluminum oxide, aluminum nitride, and silicon nitride, or an insulating layer, such as an epoxy resin. A copper pattern is disposed on a back surface of the insulating substrate 1, and the collector pattern 3, the gate pattern 6, the first emitter pattern 9, and the second emitter pattern 12 are arranged on the front surface of the insulating substrate 1. A case where the semiconductor device includes the insulating substrate 1 is shown in an example of FIG. 1, but a configuration of the insulating substrate 1 is not limited to this configuration. It is only necessary to arrange wiring patterns on the front surface, so that the insulating substrate 1 may be a resin insulating copper base plate integrated with a copper base plate without having a metal pattern on a back surface thereof. In this case, the wiring patterns are to be arranged on a front surface of the resin insulating copper base plate.

Silicon (Si) or silicon carbide (SiC) as a wide bandgap semiconductor can be used as a material for the semiconductor chip 2, for example. An Si semiconductor element or an SiC semiconductor element containing them as a substrate material corresponds to the semiconductor chip 2.

Use of the wide bandgap semiconductor as a material for the semiconductor chip 2 allows for miniaturization of the semiconductor device as the wide bandgap semiconductor has a high allowable current density and a low power loss. Examples of the semiconductor chip 2 include a power control semiconductor element (switching element), such as a metal oxide semiconductor field effect transistor (MOSFET) and an insulated gate bipolar transistor (IGBT) to control a heavy current, and a freewheeling diode, for example.

The collector electrode 4, the gate electrode 7, the first emitter electrode 10, and the second emitter electrode 13 are each formed of a plate electrode of copper and insert-molded or outsert-molded to an unillustrated case.

As described above, the collector electrode 4, the gate electrode 7, the first emitter electrode 10, and the second emitter electrode 13 are electrically connected to the collector pattern 3, the gate pattern 6, the first emitter pattern 9, and the second emitter pattern 12, respectively. A method of connecting them may be any method, such as soldering, ultrasonic joining, and joining via metal wiring, as long as the method allows for electrical connection.

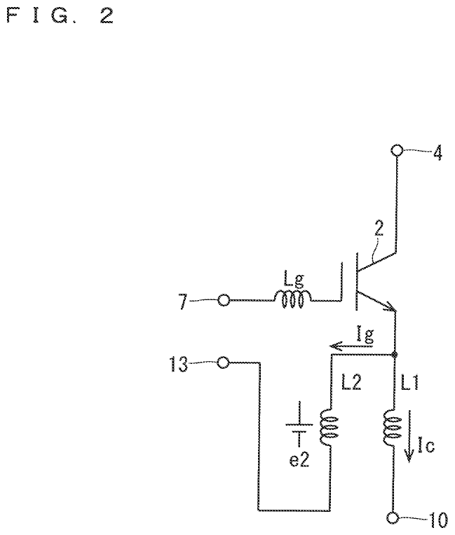

FIG. 2 is a circuit diagram of the semiconductor device illustrated in FIG. 1. In FIG. 2, L1 is a parasitic inductance of the first emitter wiring 8. L2 is a parasitic inductance of the second emitter wiring 11. Lg is a parasitic inductance of the gate wiring 5. Ic is a current (principal current) flowing through the first emitter wiring 8. Ig is a current (gate current) flowing through the second emitter wiring 11. e2 is an induced electromotive force generated in the second emitter wiring 11.

The semiconductor device according to Embodiment 1 is characterized in that the first emitter wiring 8 and the second emitter wiring 11 are arranged in parallel with each other and on the same side, and the gate wiring 5 is disposed on an opposite side from the second emitter wiring 11. In a case where a large current referenced to the surface of the semiconductor chip 2 flows through the first emitter wiring 8, the induced electromotive force (e2 shown in FIG. 2) referenced to the second emitter pattern 12 is generated in the 25 second emitter wiring 11 due to mutual induction. The induced electromotive force can suppress an increase in gate voltage caused when the semiconductor chip 2 is turned on. This leads to suppression of an increase in short circuit current, resulting in improvement in short circuit capability of the semiconductor device.

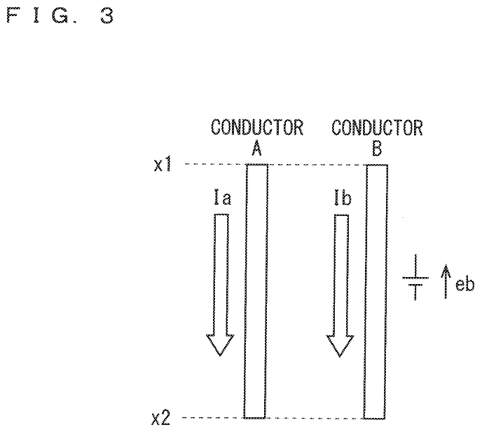

FIG. 3 is a diagram for describing a direction of the induced electromotive force generated due to mutual induction. In FIG. 3, Ia is a current flowing through a conductor A from x1 to x2. Ib is a current flowing through a conductor B from x1 to x2. eb is an induced electromotive force generated in the conductor B from x2 to x1. Assume that the current Ia flowing through the conductor A temporally increases when the induced electromotive force eb is generated in the conductor B.

As shown in FIG. 3, in a case where the currents Ia and Ib respectively flowing through the two conductors A and B arranged in parallel with each other are in the same direction, and the current Ia flowing through the conductor A temporally increases, the induced electromotive force eb is generated to suppress the current flowing through the conductor B in proportion to the amount of change in current over time (dia/dt).

WO 2017/209191 discloses an example of a configuration of a semiconductor device in which emitter wiring through which a principal current flows and emitter control wiring into which a control signal is input are arranged in parallel with each other and on the same side, but, in this configuration, gate wiring and the emitter control wiring are arranged in parallel with each other and on the same side. An induced electromotive force (induced electromotive force to suppress an increase in gate voltage) generated in the emitter control wiring due to mutual induction from the current flowing through the emitter wiring is counteracted by an induced electromotive force generated in the gate wiring, so that an increase in short circuit current cannot be suppressed, and improvement in short circuit capability cannot be expected.

On the other hand, in the configuration of the semiconductor device according to Embodiment 1, the first emitter wiring 8 (corresponding to the above-mentioned emitter wiring) and the second emitter wiring 11 (corresponding to the above-mentioned emitter control wiring) are arranged in parallel with each other and on the same side, and the gate wiring 5 is disposed on an opposite side from the second emitter wiring 11. Thus, the induced electromotive force generated due to mutual induction from the first emitter wiring 8 is not generated in the gate wiring 5 but is generated only in the second emitter wiring 11, so that the increase in short circuit current can be suppressed, and short circuit capability of the semiconductor device can be improved.

While description has been made on a 1-in-1 module as a minimum configuration of the semiconductor device according to the present disclosure with reference to FIG. 1, the present disclosure is applicable in a case where a circuit configuration is expanded to 2-in-1, 6-in-1, and the like. The present disclosure is applicable also in a case where the number of semiconductor chips 2 connected in parallel is two or more.

### Embodiment 2

A semiconductor device according to Embodiment 2 is similar to the semiconductor device illustrated in FIG. 1. The semiconductor device according to Embodiment 2 is characterized in that the second emitter pattern 12 is disposed between the collector pattern 3 and the first emitter pattern 9, and the second emitter wiring 11 is shorter than the first emitter wiring 8.

By making the second emitter wiring 11 shorter than the first emitter wiring 8, a loss of a DC component caused in the gate signal can be reduced.

### Embodiment 3

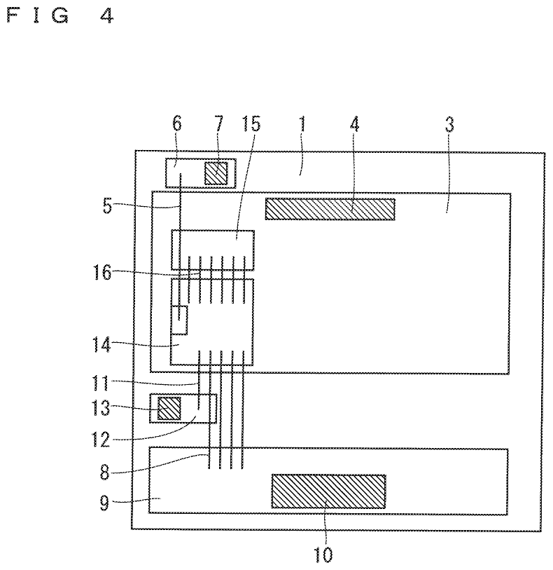

FIG. 4 is a top view illustrating one example of a configuration of a semiconductor device according to Embodiment 3. The semiconductor device according to Embodiment 3 is characterized in that the semiconductor chip 2 of the semiconductor device (see FIG. 1) according to each of Embodiments 1 and 2 separately includes a switching element 14 and a freewheeling element 15.

The freewheeling element 15 is disposed on the collector pattern 3 on the same side of the switching element 14 as the gate pattern 6. The freewheeling element 15 is connected to a surface of the switching element 14 via third emitter wiring 16 (fourth wiring). The third emitter wiring 16 is disposed on an opposite side from the second emitter wiring 11.

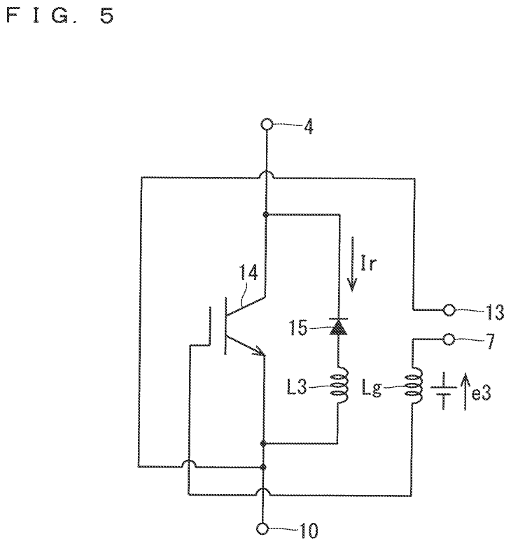

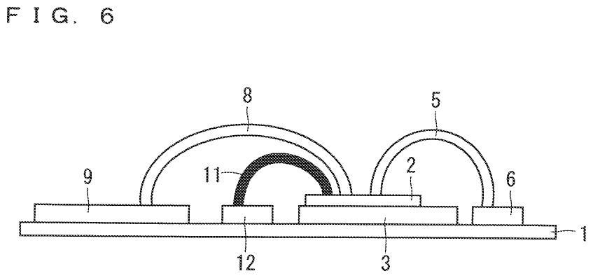

FIG. 5 is a circuit diagram of the semiconductor device illustrated in FIG. 4. In FIG. 5, L3 is a parasitic inductance of the third emitter wiring 16. Lg is the parasitic inductance of the gate wiring 5. e3 is an induced electromotive force generated in the gate wiring 5. Ir is a reverse recovery current flowing through the freewheeling element 15.

When the freewheeling element 15 performs reverse recovery operation, the reverse recovery current Ir referenced to a surface of the freewheeling element 15 flows through the third emitter wiring 16, and the induced electromotive force e3 referenced to the gate pad is generated in the gate wiring 5 due to mutual induction. The induced electromotive force e3 is exerted to turn off the switching element 14, so that turn-on of the switching element 14 due to malfunction during reverse recovery operation of the freewheeling element 15 can be prevented.

### Embodiment 4

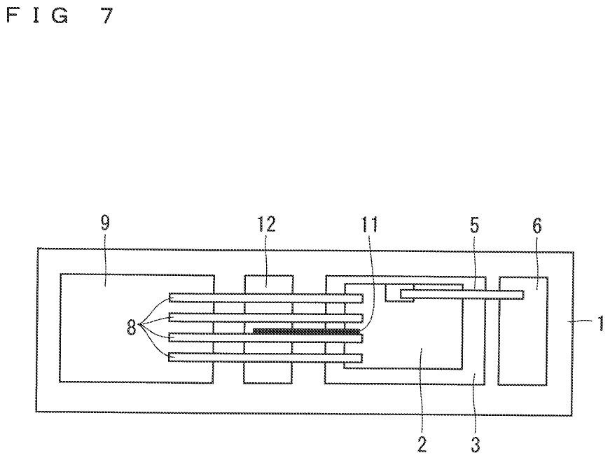

FIG. 6 is a side view illustrating one example of a configuration of a semiconductor device according to Embodiment 4. FIG. 7 is a top view of the semiconductor device illustrated in FIG. 6.

The semiconductor device according to Embodiment 4 is characterized in that the first emitter wiring 8 is disposed to extend above the second emitter wiring 11. The other configuration is similar to that of the semiconductor device according to Embodiment 1 (see FIG. 1), so that detailed description is herein omitted.

By disposing the first emitter wiring 8 so that the first emitter wiring 8 extends above the second emitter wiring 11, a larger number of metal wires can be used for emitter wiring than in the semiconductor device according to Embodiment 1 (see FIG. 1), and improvement in reliability of the semiconductor device can be expected.

While description has been made on a configuration based on the semiconductor device according to Embodiment 1 (see FIG. 1) with reference to FIG. 6, the configuration may be a configuration based on the semiconductor device according to Embodiment 3 (see FIG. 4). An effect similar to that obtained in Embodiment 4 can be obtained even in the configuration based on the semiconductor device according to Embodiment 3 (see FIG. 4).

Embodiments can freely be combined with each other and can be modified or omitted as appropriate within the scope of the present disclosure.

### APPENDICES

Various aspects of the present disclosure will collectively be described below as appendices.

### Appendix 1

A semiconductor device comprising:
an insulating substrate;
a first circuit pattern, a second circuit pattern, a third circuit pattern, and a fourth circuit pattern arranged on the insulating substrate;
a semiconductor chip and a first electrode arranged on the first circuit pattern;
a second electrode disposed on the second circuit pattern;
a third electrode disposed on the third circuit pattern; and
a fourth electrode disposed on the fourth circuit pattern, wherein
a pad disposed on the semiconductor chip and the second circuit pattern are connected via first wiring,
a surface of the semiconductor chip and the third circuit pattern are connected via second wiring,
the surface of the semiconductor chip and the fourth circuit pattern are connected via third wiring,
the second wiring and the third wiring are arranged on the same side of the surface of the semiconductor chip and in parallel with each other, and
the first wiring is disposed on an opposite side from the third wiring.

### Appendix 2

The semiconductor device according to Appendix 1, wherein
the fourth circuit pattern is disposed between the first circuit pattern and the third circuit pattern, and
the third wiring is shorter than the second wiring.

### Appendix 3

The semiconductor device according to Appendix 1 or 2, wherein
the semiconductor chip separately includes a switching element and a freewheeling element, and
fourth wiring connecting a surface of the switching element and a surface of the freewheeling element is disposed on an opposite side from the second wiring and the third wiring.

### Appendix 4

The semiconductor device according to any one of Appendices 1 to 3, wherein
the second wiring is disposed to extend above the third wiring.

### Appendix 5

The semiconductor device according to any one of Appendices 1 to 4, wherein
the first electrode is a collector electrode,
the second electrode is a gate electrode,
the third electrode is a first emitter electrode, and
the fourth electrode is a second emitter electrode.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
an insulating substrate;
a first circuit pattern, a second circuit pattern, a third circuit pattern, and a fourth circuit pattern arranged on the insulating substrate;
a semiconductor chip and a first electrode arranged on the first circuit pattern;
a second electrode disposed on the second circuit pattern;
a third electrode disposed on the third circuit pattern; and
a fourth electrode disposed on the fourth circuit pattern, wherein
a pad disposed on the semiconductor chip and the second circuit pattern are connected via first wiring,
a surface of the semiconductor chip and the third circuit pattern are connected via second wiring,
the surface of the semiconductor chip and the fourth circuit pattern are connected via third wiring,
the second wiring and the third wiring are arranged on the same side of the surface of the semiconductor chip and in parallel with each other, and
the first wiring is disposed on an opposite side from the third wiring.

2. The semiconductor device according to claim 1, wherein
the fourth circuit pattern is disposed between the first circuit pattern and the third circuit pattern, and
the third wiring is shorter than the second wiring.

3. The semiconductor device according to claim 1, wherein
the semiconductor chip separately includes a switching element and a freewheeling element, and
fourth wiring connecting a surface of the switching element and a surface of the freewheeling element is disposed on an opposite side from the second wiring and the third wiring.

4. The semiconductor device according to claim 2, wherein
the semiconductor chip separately includes a switching element and a freewheeling element, and
fourth wiring connecting a surface of the switching element and a surface of the freewheeling element is disposed on an opposite side from the second wiring and the third wiring.

5. The semiconductor device according to claim 1, wherein
the second wiring is disposed to extend above the third wiring.

6. The semiconductor device according to claim 2, wherein
the second wiring is disposed to extend above the third wiring.

7. The semiconductor device according to claim 3, wherein
the second wiring is disposed to extend above the third wiring.

8. The semiconductor device according to claim 4, wherein
the second wiring is disposed to extend above the third wiring.

9. The semiconductor device according to claim 1, wherein
the first electrode is a collector electrode,
the second electrode is a gate electrode,
the third electrode is a first emitter electrode, and
the fourth electrode is a second emitter electrode.

10. The semiconductor device according to claim 2, wherein
the first electrode is a collector electrode,
the second electrode is a gate electrode,
the third electrode is a first emitter electrode, and
the fourth electrode is a second emitter electrode.

11. The semiconductor device according to claim 3, wherein
the first electrode is a collector electrode,
the second electrode is a gate electrode,
the third electrode is a first emitter electrode, and
the fourth electrode is a second emitter electrode.

12. The semiconductor device according to claim 4, wherein
the first electrode is a collector electrode,
the second electrode is a gate electrode,
the third electrode is a first emitter electrode, and
the fourth electrode is a second emitter electrode.

13. The semiconductor device according to claim 5, wherein
the first electrode is a collector electrode,
the second electrode is a gate electrode,
the third electrode is a first emitter electrode, and
the fourth electrode is a second emitter electrode.

14. The semiconductor device according to claim 6, wherein
the first electrode is a collector electrode,
the second electrode is a gate electrode,
the third electrode is a first emitter electrode, and
the fourth electrode is a second emitter electrode.

15. The semiconductor device according to claim 7, wherein
the first electrode is a collector electrode,
the second electrode is a gate electrode,
the third electrode is a first emitter electrode, and
the fourth electrode is a second emitter electrode.

16. The semiconductor device according to claim 8, wherein
the first electrode is a collector electrode,
the second electrode is a gate electrode,
the third electrode is a first emitter electrode, and
the fourth electrode is a second emitter electrode.
